(19) United States
(12) Patent Application Publication
(10) Pub. No.: US 2012/0074102 A1
(43) Pub. Date: Mar. 29, 2012

(54) SUBSTRATE PROCESSING APPARATUS AND SUBSTRATE PROCESSING METHOD

(76) Inventors: Keiji MAGARA, Kyoto (JP); Akio HASHIZUME, Kyoto (JP); Takashi OTA, Kyoto (JP)

(21) Appl. No.: 13/246,258

(22) Filed: Sep. 27, 2011

(30) Foreign Application Priority Data
Sep. 29, 2010 (JP) 2010-219370

(51) Int. Cl. C23F 1/46; C23F 1/00; C23F 1/16; H01L 21/306; C23F 1/08

(52) U.S. Cl. 216/83; 156/345.11; 156/345.21; 156/345.15; 156/345.18; 156/345.23

(57) ABSTRACT

Phosphoric acid, sulfuric acid, and water are supplied to a flow path for a processing liquid from a first tank to a substrate held by a substrate holding unit. As a result, a mixed liquid containing the phosphoric acid, the sulfuric acid, and the water is generated. A liquid containing the sulfuric acid and a liquid containing the water are mixed together in the flow path, and the temperature of the mixed liquid containing the phosphoric acid, the sulfuric acid, and the water rises. A mixed liquid containing a phosphoric acid aqueous solution whose temperature is close to its boiling point is supplied to the substrate held by the substrate holding unit.

### BACKGROUND OF THE INVENTION

1. Field of the Invention

This invention relates to a substrate processing apparatus and a substrate processing method for processing substrates. Examples of substrates to be processed include semiconductor wafers, substrates for liquid crystal displays, substrates for plasma displays, substrates for FEDs (Field Emission Displays), substrates for optical disks, substrates for magnetic disks, substrates for magneto-optical disks, substrates for photomasks, ceramic substrates, and substrates for solar cells.

2. Description of Related Art

In a production process in which a semiconductor device, a liquid crystal display device, or the like is produced, etching is performed when needed. In the etching, a high-temperature phosphoric acid aqueous solution that serves as an etchant is supplied to the surface of a substrate on which a silicon nitride film and a silicon oxide film are formed, and then the silicon nitride film is selectively removed.

In a batch type substrate processing apparatus that processes a plurality of substrates in a batch manner, a plurality of substrates are soaked for a fixed time in a processing tank in which a high-temperature phosphoric acid aqueous solution is stored (see Japanese Published Unexamined Patent Application No. 2007-258405, for example.)

On the other hand, in a single substrate processing type substrate processing apparatus that processes substrates one by one, a high-temperature phosphoric acid aqueous solution stored in a tank is supplied to a nozzle via a pipe, and is discharged from the nozzle toward a substrate held by a spin chuck (see Japanese Published Unexamined Patent Application No. 2007-258405, for example.)

The batch type substrate processing apparatus is required to soak substrates in the phosphoric acid aqueous solution stored in the processing tank for a fixed time or longer in order to uniformly perform etching. Therefore, the same processing time is needed even when a plurality of substrates are processed in a batch manner and even when a single substrate is processed.

On the other hand, the single substrate processing type substrate processing apparatus can uniformly process one substrate in a short time. However, in the single substrate processing type substrate processing apparatus, a phosphoric acid aqueous solution is deprived of its heat by the pipe and the nozzle during the flow of the phosphoric acid aqueous solution through the pipe and the nozzle, and, as a result, the temperature of the phosphoric acid aqueous solution falls. Therefore, the phosphoric acid aqueous solution having a lower temperature than that of the phosphoric acid aqueous solution stored in the tank is supplied to a substrate.

The selection ratio (i.e., removal amount of silicon nitride film/removal amount of silicon oxide film) and the etching rate of the silicon nitride film (i.e., removal amount per unit time) are the highest when the temperature of the phosphoric acid aqueous solution supplied to the substrate is close to its boiling point. However, in the single substrate processing type substrate processing apparatus, the temperature of the phosphoric acid aqueous solution falls until the phosphoric acid aqueous solution is supplied to the substrate even if the temperature of the phosphoric acid aqueous solution is regulated to be close to the boiling point in the tank, and therefore it is difficult to supply the phosphoric acid aqueous solution whose temperature is close to its boiling point.

### SUMMARY OF THE INVENTION

It is an object of the present invention to provide a substrate processing apparatus and a substrate processing method that are capable of restraining or preventing a fall in temperature of a processing liquid that is supplied to substrates.

One embodiment of the present invention provides a substrate processing apparatus that processes a substrate by a mixed liquid containing phosphoric acid, sulfuric acid, and water, and the substrate processing apparatus includes a substrate holding unit that holds a substrate and a mixed liquid supply unit. The mixed liquid supply unit includes a first tank in which a processing liquid to be supplied to the substrate held by the substrate holding unit is stored, and a flow path for the processing liquid leading from the first tank to the substrate held by the substrate holding unit. The mixed liquid supply unit raises a temperature of a mixed liquid containing phosphoric acid, sulfuric acid, and water by supplying the phosphoric acid, the sulfuric acid, and the water to the flow path and by mixing a liquid containing the sulfuric acid and a liquid containing the water in the flow path. The mixed liquid supply unit supplies a mixed liquid containing a phosphoric acid aqueous solution whose temperature is close to its boiling point to the substrate.

According to this structure, phosphoric acid (liquid), sulfuric acid (liquid), and water are supplied to the flow path for a processing liquid leading from the first tank to the substrate held by the substrate holding unit. Phosphoric acid, sulfuric acid, and water may be separately supplied from a plurality of processing liquid supply sources including the first tank to the flow path, or may be supplied to the flow path in a state of being mixed with other processing liquids. In more detail, for example, a phosphoric acid aqueous solution and a sulfuric acid aqueous solution may be supplied to the flow path, or water and a mixed liquid containing phosphoric acid, sulfuric acid, and water may be supplied to the flow path. A liquid containing sulfuric acid and a liquid containing water are mixed together in the flow path by supplying phosphoric acid, sulfuric acid, and water to the flow path.

Sulfuric acid generates dilution heat by being diluted by water. Therefore, dilution heat is generated bymixing a liquid containing sulfuric acid and a liquid containing water together. A mixed liquid containing phosphoric acid, sulfuric acid, and water is heated in the flow path by this dilution heat. Therefore, even if a mixed liquid containing phosphoric acid, sulfuric acid, and water is deprived of its heat by pipes or nozzles, this dilution heat is applied to the mixed liquid, and the mixed liquid is restrained or prevented from being reduced in temperature. Hence, a phosphoric acid aqueous solution contained in the mixed liquid is heated, and the mixed liquid containing a phosphoric acid aqueous solution whose temperature is close to its boiling point, i.e., the mixed liquid containing a phosphoric acid aqueous solution whose temperature is its boiling point and/or a phosphoric acid aqueous solution whose temperature is approximately its boiling point are/is supplied to a substrate.

The mixed liquid supply unit may further include a first nozzle that discharges a processing liquid toward the substrate held by the substrate holding unit, and a first supply pipe through which a processing liquid to be supplied to the first nozzle from the first tank flows. The flow path may include an inside of the first supply pipe, an inside of the first nozzle, and a space between the first nozzle and the substrate held by the substrate holding unit.

In this case, a liquid containing sulfuric acid and a liquid containing water are mixed together in at least one position among the inside of the first supply pipe, the inside of the first nozzle, and the space between the first nozzle and the substrate held by the substrate holding unit. In other words, a liquid containing sulfuric acid and a liquid containing water are mixed together immediately before being supplied to the substrate or simultaneously with being supplied to the substrate. As a result, the mixed liquid that contains phosphoric acid, sulfuric acid, and water and whose temperature has been reliably raised is supplied to the substrate.

The first tank may store a mixed liquid that contains at least two among phosphoric acid, sulfuric acid, and water.

In this case, a phosphoric acid aqueous solution, a sulfuric acid aqueous solution, a mixed liquid containing phosphoric acid and sulfuric acid, or a mixed liquid containing phosphoric acid, sulfuric acid, and water is stored in the first tank. In other words, at least two among phosphoric acid, sulfuric acid, and water are beforehand mixed together in the first tank. Therefore, a mixed liquid (mixed liquid containing phosphoric acid, sulfuric acid, and water) in which at least two among phosphoric acid, sulfuric acid, and water have been sufficiently mixed together can be supplied to the substrate.

The mixed liquid supply unit may include a water supply pipe through which a liquid that contains water to be supplied to the flow path flows, a flow regulating valve that regulates a flow rate of the liquid flowing through the water supply pipe, a temperature detector that detects a temperature of a mixed liquid containing phosphoric acid, sulfuric acid, and water in the flow path, and a flow controller that controls the flow regulating valve based on an output emitted from the temperature detector.

In this case, the water-containing liquid is supplied from the water supply pipe to the flow path. Therefore, the sulfuric-acid-containing liquid and the water-containing liquid are reliably mixed together in the flow path, and dilution heat is generated. The temperature of the mixed liquid containing phosphoric acid, sulfuric acid, and water is detected by the temperature detector. The flow controller controls the flow regulating valve based on an output emitted from the temperature detector. As a result, the flow rate of the water-containing liquid supplied to the flow path is regulated.

The flow controller can increase the dilution heat by increasing the flow rate of the water-containing liquid supplied to the flow path. On the other hand, the flow controller can decrease the dilution heat by decreasing the flow rate of the water-containing liquid supplied to the flow path. Therefore, the flow controller can regulate the temperature of the mixed liquid containing phosphoric acid, sulfuric acid, and water by regulating the flow rate of the water-containing liquid supplied to the flow path. As a result, a mixed liquid containing a phosphoric acid aqueous solution whose temperature is close to its boiling point can be reliably supplied to a substrate.

The first tank may include a mixed liquid tank in which a mixed liquid containing phosphoric acid, sulfuric acid, and water is stored. The substrate processing apparatus may further include a collecting unit that collects the mixed liquid containing phosphoric acid, sulfuric acid, and water supplied to the substrate held by the substrate holding unit and that supplies the mixed liquid collected thereby to the mixed liquid tank.

In this case, the mixed liquid containing phosphoric acid, sulfuric acid, and water is stored in the mixed liquid tank. The mixed liquid stored in the mixed liquid tank is supplied to the substrate held by the substrate holding unit along the flow path. Furthermore, the mixed liquid containing phosphoric acid, sulfuric acid, and water supplied to the substrate is collected by the collecting unit. The mixed liquid collected thereby is then supplied to the mixed liquid tank. Therefore, the collected mixed liquid is again supplied to the substrate, and is reused. Hence, the consumption of the mixed liquid is reduced.

When a substrate on which a silicon nitride film is formed is processed by the mixed liquid containing phosphoric acid, sulfuric acid, and water (i.e., when etching is performed thereby), siloxane is contained in the collected mixed liquid. Therefore, in this case, the mixed liquid containing siloxane is supplied to the mixed liquid tank, and is again supplied to the substrate along the flow path. Siloxane is a compound containing a siloxane linkage (Si—O—Si). If siloxane is contained in the mixed liquid containing phosphoric acid, sulfuric acid, and water, the selection ratio is heightened. Therefore, the selection ratio can be heightened in etching by reusing the collected mixed liquid.

The mixed liquid supply unit may further include a phosphoric acid supply unit that supplies a liquid containing phosphoric acid to at least one of the mixed liquid tank and the flow path, and a sulfuric acid supply unit that supplies a liquid containing sulfuric acid to at least one of the mixed liquid tank and the flow path.

In this case, the phosphoric-acid-containing liquid and the sulfuric-acid-containing liquid are supplied to at least one of the mixed liquid tank and the flow path. As a result, the phosphoric-acid-containing liquid and the sulfuric-acid-containing liquid are mixed with a mixed liquid collected by the collecting unit. Therefore, the mixed liquid is diluted by the phosphoric-acid-containing liquid and the sulfuric-acid-containing liquid. Therefore, if siloxane is contained in the mixed liquid collected, siloxane is restrained from rising in concentration. Hence, a mixed liquid having a high concentration of siloxane (i.e., a mixed liquid containing phosphoric acid, sulfuric acid, and water containing siloxane) is restrained or prevented from being supplied to a substrate. Therefore, a compound containing silicon precipitated from the mixed liquid can be restrained or prevented from adhering to the substrate.

Another embodiment of the present invention provides a substrate processing method of processing a substrate by a mixed liquid containing phosphoric acid, sulfuric acid, and water, and the substrate processing method includes a temperature raising step of raising a temperature of a mixed liquid containing phosphoric acid, sulfuric acid, and water by supplying the phosphoric acid, the sulfuric acid, and the water to a flow path for a processing liquid leading from a first tank, in which the processing liquid to be supplied to a substrate is stored, to the substrate and by mixing a liquid containing the sulfuric acid and a liquid containing the water in the flow path, and a mixed liquid supply step of supplying a mixed liquid that has been generated in the temperature raising step and that contains a phosphoric acid aqueous solution whose temperature is close to its boiling point to the substrate. According to this method, the same effect as above can be fulfilled.

Still another embodiment of the present invention provides a substrate processing apparatus including a substrate holding unit that holds a substrate, and a mixed liquid supply unit that mixes a first liquid and a second liquid that are heated by being mixed together in a flow path for a processing liquid leading to a substrate held by the substrate holding unit and that supplies a mixed liquid containing the first liquid and the second liquid to the substrate.

According to this structure, the first liquid and the second liquid are mixed together in the flow path for a processing liquid leading to a substrate held by the substrate holding unit. As a result, heat is generated. Therefore, a mixed liquid containing the first liquid and the second liquid is heated in the flow path by heat generated by a mixture of the first liquid and the second liquid. Therefore, even if the mixed liquid containing the first liquid and the second liquid is deprived of its heat by pipes or nozzles, heat generated by a mixture of the first liquid and the second liquid is applied to the mixed liquid, and the mixed liquid is restrained or prevented from being reduced in temperature. Hence, the mixed liquid to be supplied to a substrate can be restrained or prevented from being lowered in temperature.

The mixed liquid supply unit may include a first liquid supply unit that supplies the first liquid to be mixed with the second liquid in the flow path, and a second liquid supply unit that supplies the second liquid to be mixed with the first liquid in the flow path. The first liquid supply unit may include a first tank in which the first liquid is stored, a first supply pipe connected to the first tank, and a first nozzle that is connected to the first supply pipe and that discharges the first liquid toward the substrate held by the substrate holding unit. The first tank, the first supply pipe, the first nozzle, and a space between the first nozzle and the substrate may define the flow path.

The second liquid supply unit may include a second tank in which the second liquid is stored, and a second supply pipe that is connected to the second tank and that is connected to at least one of the first supply pipe and the first nozzle.

The second liquid supply unit may include a second tank in which the second liquid is stored, a second supply pipe connected to the second tank, and a second nozzle that is connected to the second supply pipe and that discharges the second liquid toward the substrate held by the substrate holding unit.

The second liquid supply unit may include at least one among a tank pipe that is connected to the first tank and that supplies the second liquid to the first tank, an intermediate pipe that is connected to at least one of the first supply pipe and the first nozzle and that supplies the second liquid to at least one of the first supply pipe and the first nozzle, and a second nozzle that discharges the second liquid toward the substrate held by the substrate holding unit.

The mixed liquid supply unit may include a first tank in which the first liquid is stored, a first circulation route along which the first liquid stored in the first tank circulates, and a first heater that heats the first liquid circulating along the first circulation route. The mixed liquid supply unit may further include a second tank in which the second liquid is stored, a second circulation route along which the second liquid stored in the second tank circulates, and a second heater that heats the second liquid circulating along the second circulation route.

The mixed liquid supply unit may include a second tank in which the second liquid is stored, a second circulation route along which the second liquid stored in the second tank circulates, and a second heater that heats the second liquid circulating along the second circulation route. In this case, the mixed liquid supply unit may further include a concentration detector that detects a concentration of the second liquid stored in the second tank, a water supply pipe that supplies water to the second tank, a water supply valve interposed in the water supply pipe, and a concentration controller that opens and closes the water supply valve based on an output emitted from the concentration detector.

The mixed liquid supply unit may include a first supply pipe through which the first liquid to be mixed with the second liquid in the flow path flows, and a first flow regulating valve interposed in the first supply pipe. In this case, the mixed liquid supply unit may further include a second supply pipe through which the second liquid to be mixed with the first liquid in the flow path flows, and a second flow regulating valve interposed in the second supply pipe.

The mixed liquid supply unit may include a second supply pipe through which the second liquid to be mixed with the first liquid in the flow path flows, a second flow regulating valve interposed in the second supply pipe, a temperature detector that detects a temperature of the mixed liquid containing the first liquid and the second liquid in the flow path, and a flow controller that controls the second flow regulating valve based on an output emitted from the temperature detector.

The mixed liquid supply unit may include a mixed liquid tank in which the mixed liquid containing the first liquid and the second liquid is stored. The substrate processing apparatus may further include a collecting unit that collects the mixed liquid supplied to the substrate held by the substrate holding unit and that supplies the mixed liquid collected thereby to the mixed liquid tank. In this case, the mixed liquid supply unit may include a first supply unit that supplies the first liquid to at least one of the mixed liquid tank and the flow path, and a second supply unit that supplies the second liquid to at least one of the mixed liquid tank and the flow path.

The substrate holding unit may be a unit that horizontally holds a substrate. In this case, the substrate holding unit may be a unit that rotates the substrate around a vertical axis passing through a center of the substrate while horizontally holding the substrate. In other words, the substrate processing apparatus may be a single substrate processing type substrate processing apparatus that processes substrates one by one.

The mixed liquid supply unit may be a unit that supplies phosphoric acid, sulfuric acid, and water to the flow path, that mixes the first liquid containing at least the sulfuric acid and the second liquid containing at least the water together in the flow path, and that supplies the mixed liquid containing the phosphoric acid, the sulfuric acid, and the water to the substrate held by the substrate holding unit.

Still another embodiment of the present invention provides a substrate processing method including a mixed liquid supply step of mixing a first liquid and a second liquid that are heated by being mixed together in a flow path for a processing liquid leading to a substrate held by a substrate holding unit, and thereby supplying a mixed liquid containing the first liquid and the second liquid to the substrate. According to this method, the same effect as above can be fulfilled.

The mixed liquid supply step may include a step of mixing the first liquid and the second liquid together in at least one among a first tank in which the first liquid is stored, a first supply pipe connected to the first tank, a first nozzle that is connected to the first supply pipe and that discharges the first liquid toward the substrate held by the substrate holding unit, and a space between the first nozzle and the substrate.

The mixed liquid supply step may include a first heating step of raising a temperature of the first liquid stored in the first tank by a first heater. In this case, the mixed liquid supply step may further include a second heating step of raising a temperature of the second liquid stored in the second tank by a second heater.

The mixed liquid supply step may include a second heating step of raising a temperature of the second liquid stored in the second tank by a second heater, and a concentration regulating step of regulating a concentration of the second liquid stored in the second tank by supplying water to the second tank.

The mixed liquid supply step may include a mixing ratio changing step of changing a mixing ratio between the first liquid and the second liquid that are mixed together in the flow path.

The mixed liquid supply step may include a flow rate changing step of changing a flow rate of the second liquid supplied to the flow path in accordance with a temperature of a mixed liquid containing the first liquid and the second liquid in the flow path.

The substrate processing method may further include a collecting step of collecting the mixed liquid supplied to the substrate in the mixed liquid supply step and thereafter supplying the mixed liquid collected in the collecting step to the mixed liquid tank in which the mixed liquid containing the first liquid and the second liquid is stored.

The substrate processing method may further include a mixed liquid concentration regulating step of supplying at least one of the first liquid and the second liquid to the mixed liquid collected in the collecting step and thereby regulating a concentration of the mixed liquid.

The mixed liquid supply step may be a step of supplying the mixed liquid containing the first liquid and the second liquid to the substrate horizontally held by the substrate holding unit. In this case, the mixed liquid supply step may be a step of supplying the mixed liquid containing the first liquid and the second liquid to the substrate that is horizontally held by the substrate holding unit and that is rotating around a vertical axis passing through a center of the substrate by the substrate holding unit.

The mixed liquid supply step may be a step of supplying phosphoric acid, sulfuric acid, and water to the flow path, mixing the first liquid containing at least the sulfuric acid and the second liquid containing at least the water together in the flow path, and supplying the mixed liquid containing the phosphoric acid, the sulfuric acid, and the water to the substrate held by the substrate holding unit.

The substrate processing method may be a method of processing a substrate on which a nitride film is formed, and the mixed liquid supply step may be a step of etching the nitride film.

The aforementioned or other objects, features, and effects will be clarified by the following description of embodiments given below with reference to the accompanying drawings.

### BRIEF DESCRIPTION OF THE DRAWINGS

FIG. 1 is a schematic view showing a schematic structure of a substrate processing apparatus according to a first embodiment of the present invention.

FIG. 2 is a process chart for describing a first processing example in which a substrate is processed by the substrate processing apparatus according to the first embodiment of the present invention.

FIG. 3 is a graph showing a relationship among the concentration of phosphoric acid in a phosphoric acid aqueous solution, the temperature of the phosphoric acid aqueous solution, and the etching rate of a silicon nitride film.

FIG. 4 is a schematic view showing a schematic structure of a substrate processing apparatus according to a first modification example of the first embodiment of the present invention.

FIG. 5 is a schematic view showing a schematic structure of a substrate processing apparatus according to a second modification example of the first embodiment of the present invention.

FIG. 6 is a schematic view showing a schematic structure of a substrate processing apparatus according to a third modification example of the first embodiment of the present invention.

FIG. 7 is a schematic view showing a schematic structure of a substrate processing apparatus according to a fourth modification example of the first embodiment of the present invention.

FIG. 8 is a schematic view showing a schematic structure of a substrate processing apparatus according to a second embodiment of the present invention.

FIG. 9 is a schematic view showing a schematic structure of a substrate processing apparatus according to a third embodiment of the present invention.

FIG. 10 is a schematic view showing a schematic structure of a substrate processing apparatus according to a fourth embodiment of the present invention.

FIG. 11 is a schematic view showing a schematic structure of a substrate processing apparatus according to a fifth embodiment of the present invention.

### DETAILED DESCRIPTION OF PREFERRED EMBODIMENTS

### First Embodiment

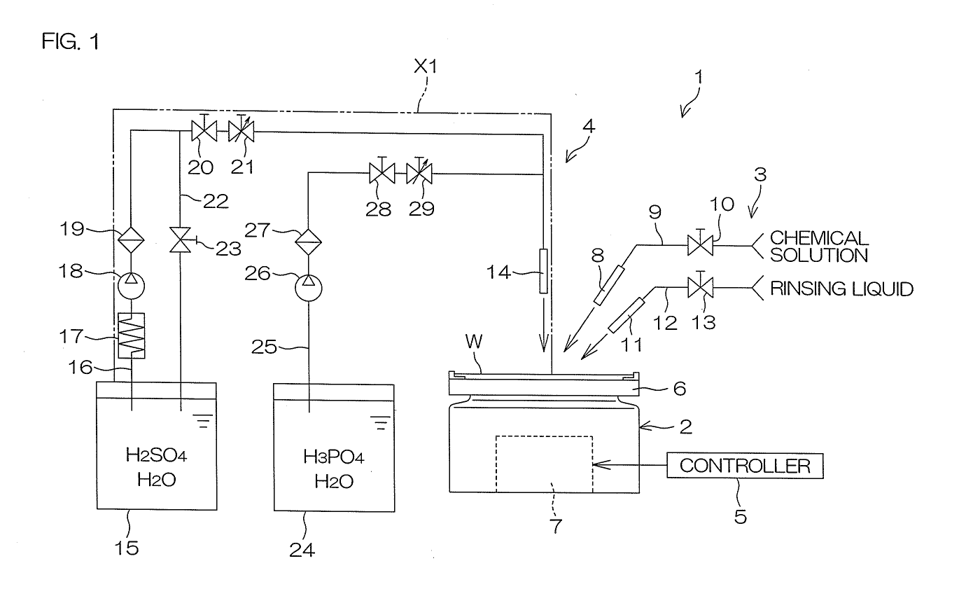

FIG. 1 is a schematic view showing a schematic structure of a substrate processing apparatus 1 according to a first embodiment of the present invention.

The substrate processing apparatus 1 is a single substrate processing type substrate processing apparatus that processes circular substrates W, such as semiconductor wafers, one by one. The substrate processing apparatus 1 includes a spin chuck 2 (a substrate holding unit) that horizontally holds and rotates a substrate W, a processing liquid supply unit 3 that supplies a processing liquid, such as a chemical solution or a rinsing liquid, to the substrate W held by the spin chuck 2, a mixed liquid supply unit 4 that supplies a mixed liquid containing phosphoric acid, sulfuric acid, and water to the substrate W held by the spin chuck 2, and a controller 5 (a flow controller, a concentration controller) that controls the operation of constituent devices, such as the spin chuck 2, of the substrate processing apparatus 1 and that controls the opening and closing of valves.

The spin chuck 2 includes a spin base 6 that horizontally holds and rotates the substrate W around a vertical axis passing through the center of the substrate W and a spin motor 7 that rotates the spin base 6 around the vertical axis. The spin chuck 2 may be a gripping type substrate holding unit that horizontally holds the substrate W by gripping the substrate W in a horizontal direction, or, alternatively, may be a vacuum-type substrate holding unit that horizontally holds the substrate W by sucking the lower surface (rear surface) of the substrate W. In the first embodiment, the spin chuck 2 is a gripping type substrate holding unit. The spin motor 7 is controlled by the controller 5.

The processing liquid supply unit 3 includes a chemical solution nozzle 8, a chemical solution supply pipe 9, and a chemical solution valve 10. The chemical solution supply pipe 9 is connected to the chemical solution nozzle 8. The chemical solution valve 10 is interposed in the chemical solution supply pipe 9. When the chemical solution valve 10 is opened, a chemical solution is supplied from the chemical solution supply pipe 9 to the chemical solution nozzle 8. When the chemical solution valve 10 is closed, the chemical solution stops being supplied from the chemical solution supply pipe 9 to the chemical solution nozzle 8. The chemical solution discharged from the chemical solution nozzle 8 is supplied to the central portion of an upper surface of the substrate W held by the spin chuck 2. A solution containing at least one among sulfuric acid, acetic acid, nitric acid, hydrochloric acid, hydrofluoric acid, aqueous ammonia, hydrogen peroxide solution, organic acid (e.g., citric acid or oxalic acid), organic alkali (e.g., tetramethylammonium hydroxide (TMAH)), surfactant, and corrosion inhibitor can be mentioned as the chemical solution.

The processing liquid supply unit 3 includes a rinsing liquid nozzle 11, a rinsing liquid supply pipe 12, and a rinsing liquid valve 13. The rinsing liquid supply pipe 12 is connected to the rinsing liquid nozzle 11. The rinsing liquid valve 13 is interposed in the rinsing liquid supply pipe 12. When the rinsing liquid valve 13 is opened, a rinsing liquid is supplied from the rinsing liquid supply pipe 12 to the rinsing liquid nozzle 11. When the rinsing liquid valve 13 is closed, the rinsing liquid stops being supplied from the rinsing liquid supply pipe 12 to the rinsing liquid nozzle 11. The rinsing liquid discharged from the rinsing liquid nozzle 11 is supplied to the central portion of the upper surface of the substrate W held by the spin chuck 2. Pure water (deionized water), carbonated water, electrolyzed ion water, hydrogen water, ozone water, or aqueous hydrochloric acid of dilute concentration (e.g., about 10 to 100 ppm) can be mentioned as the rinsing liquid.

The mixed liquid supply unit 4 includes a first nozzle 14 that discharges a processing liquid toward the central portion of the upper surface of the substrate W held by the spin chuck 2, a first tank 15 in which a processing liquid is stored, a first supply pipe 16 by which the first nozzle 14 and the first tank 15 are connected together, a first heater 17, a first pump 18, a first filter 19, a first supply valve 20, and a first flow regulating valve 21 that are interposed in the first supply pipe 16, a first return pipe 22 by which the first tank 15 and the first supply pipe 16 are connected together, and a first return valve 23 interposed in the first return pipe 22. The mixed liquid supply unit 4 further includes a second tank 24 in which a processing liquid is stored, a second supply pipe 25 (an intermediate pipe) by which the first supply pipe 16 and the second tank 24 are connected together, and a second pump 26, a second filter 27, a second supply valve 28, and a second flow regulating valve 29 that are interposed in the second supply pipe 25.

A processing liquid stored in the first tank 15 is supplied to the first nozzle 14 via the first supply pipe 16, and is discharged from the first nozzle 14 toward the central portion of the upper surface of the substrate W held by the spin chuck 2. In other words, the mixed liquid supply unit 4 has a flow path X1 for a processing liquid leading from the first tank 15 to the substrate W held by the spin chuck 2. A processing liquid stored in the first tank 15 is supplied to the substrate W held by the spin chuck 2 along the flow path X1. A processing liquid stored in the second tank 24 is supplied to the substrate W held by the spin chuck 2 along a portion of the flow path X1. The flow path X1 includes the inside of the first tank 15, the inside of the first supply pipe 16, the inside of the first nozzle 14, and a space between the first nozzle 14 and the substrate W held by the spin chuck 2.

A processing liquid containing at least one among phosphoric acid, sulfuric acid, and water is stored in each of the first tank 15 and the second tank 24. In the first embodiment, a sulfuric acid aqueous solution is stored in the first tank 15, and a phosphoric acid aqueous solution is stored in the second tank 24. The sulfuric acid aqueous solution stored in the first tank 15 may be concentrated sulfuric acid whose concentration is 90% or more, or may be dilute sulfuric acid whose concentration is less than 90%. The temperature of the sulfuric acid aqueous solution stored in the first tank 15 is regulated to fall within the range of, for example, 60° C. to 190° C. In the first embodiment, concentrated sulfuric acid that has a temperature greater than a boiling point of the phosphoric acid aqueous solution stored in the second tank 24 is stored in the first tank 15. On the other hand, the concentration of phosphoric acid in the phosphoric acid aqueous solution stored in the second tank 24 is, for example, 10% to 85%. The phosphoric acid aqueous solution stored in the second tank 24 does not undergo temperature regulation, and has room temperature (about 20° C. to 30° C.). In the first embodiment, the phosphoric acid aqueous solution whose concentration is 85% and whose temperature is room temperature is stored in the second tank 24.

One end of the first supply pipe 16 is connected to the first tank 15, and the other end of the first supply pipe 16 is connected to the first nozzle 14. The first heater 17, the first pump 18, the first filter 19, the first supply valve 20, and the first flow regulating valve 21 are interposed in the first supply pipe 16 in this order from the side of the first tank 15. The first return pipe 22 is connected to the first supply pipe 16 between the first filter 19 and the first supply valve 20. The sulfuric acid aqueous solution stored in the first tank 15 is supplied to the first supply pipe 16 by a sucking force of the first pump 18. The sulfuric acid aqueous solution pumped out from the first tank 15 by the first pump 18 is heated by the first heater 17. Furthermore, the sulfuric acid aqueous solution pumped out by the first pump 18 is filtered by the first filter 19. As a result, foreign substances contained in the sulfuric acid aqueous solution are removed.

When the first supply valve 20 is opened, and the first return valve 23 is closed in a state in which the first pump 18 is being driven, the sulfuric acid aqueous solution pumped out from the first tank 15 is supplied to the first nozzle 14 via the first supply pipe 16. On the other hand, when the first supply valve 20 is closed, and the first return valve 23 is opened in a state in which the first pump 18 is being driven, the sulfuric acid aqueous solution pumped out from the first tank 15 returns to the first tank 15 via the first supply pipe 16 and the first return pipe 22. Therefore, the sulfuric acid aqueous solution circulates along a first circulation route including the first supply pipe 16, the first return pipe 22, and the first tank 15. Hence, the sulfuric acid aqueous solution stored in the first tank 15 is evenly heated by the first heater 17, and the liquid temperature of the sulfuric acid aqueous solution is regulated.

One end of the second supply pipe 25 is connected to the second tank 24, and the other end of the second supply pipe 25 is connected to the first supply pipe 16 downstream from the first supply valve 20 (i.e., on the side of the first nozzle 14). The second pump 26, the second filter 27, the second supply valve 28, and the second flow regulating valve 29 are interposed in the second supply pipe 25 in this order from the side of the second tank 24. The phosphoric acid aqueous solution stored in the second tank 24 is supplied to the second supply pipe 25 by a sucking force of the second pump 26. As a result, the phosphoric acid aqueous solution stored in the second tank 24 is supplied to the first supply pipe 16 via the second supply pipe 25. The phosphoric acid aqueous solution pumped out by the second pump 26 is filtered by the second filter 27. As a result, foreign substances contained in the phosphoric acid aqueous solution are removed.

When the first supply valve 20 and the second supply valve 28 are opened, and the first return valve 23 is closed in a state in which the first pump 18 and the second pump 26 are being driven, the sulfuric acid aqueous solution stored in the first tank 15 and the phosphoric acid aqueous solution stored in the second tank 24 are supplied to the first supply pipe 16. As a result, the sulfuric acid aqueous solution that has a flow rate corresponding to the valve opening of the first flow regulating valve 21 and the phosphoric acid aqueous solution having a flow rate corresponding to the valve opening of the second flow regulating valve 29 are mixed together in the first supply pipe 16, and, as a result, a mixed liquid containing phosphoric acid, sulfuric acid, and water is supplied to the first nozzle 14. Thereafter, the mixed liquid containing phosphoric acid, sulfuric acid, and water is discharged from the first nozzle 14 toward the central portion of the upper surface of the substrate W held by the spin chuck 2. Hence, the mixed liquid containing phosphoric acid, sulfuric acid, and water is supplied to the substrate W held by the spin chuck 2.

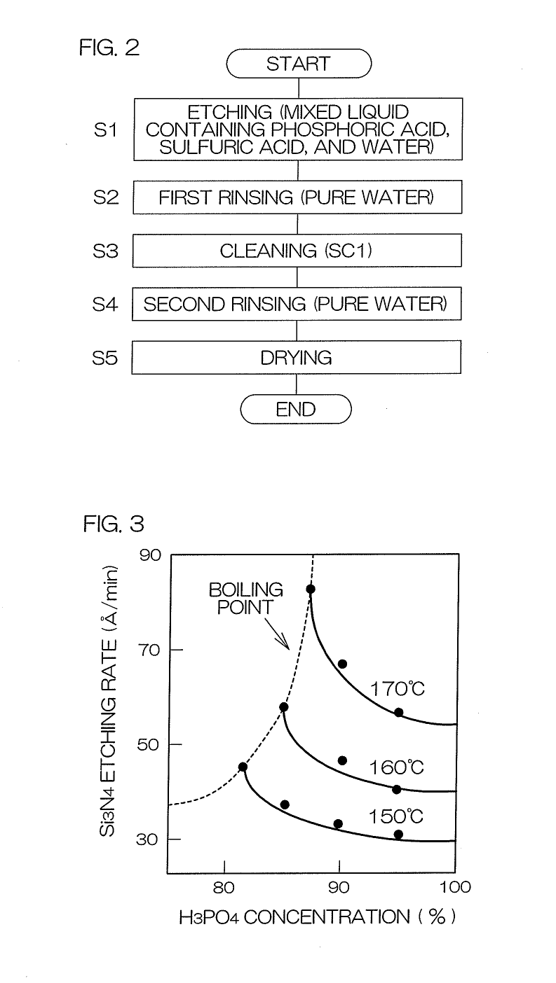

FIG. 2 is a process chart for describing a first processing example in which a substrate W is processed by the substrate processing apparatus 1 according to the first embodiment of the present invention. A description will be hereinafter given of a processing example in which a mixed liquid that serves as an etchant and that contains phosphoric acid, sulfuric acid, and water is supplied to a substrate W on which a silicon nitride film (Si₃N₄ film) and a silicon oxide film (SiO₂ film) are formed, so that the silicon nitride film is selectively removed. Additionally, reference is hereinafter made to FIG. 1 and FIG. 2.

An unprocessed substrate W is transferred by a transfer robot (not shown), and is placed on the spin chuck 2 in a state in which a front surface of the substrate W, which is a device forming surface, is directed, for example, upwardly. Thereafter, the controller 5 allows the spin chuck 2 to hold the substrate W by controlling the spin chuck 2. Thereafter, the controller 5 allows the spin motor 7 to rotate the substrate W held by the spin chuck 2 by controlling the spin motor 7.

Thereafter, etching is performed in which a mixed liquid that serves as an etchant and that contains phosphoric acid, sulfuric acid, and water is supplied to the substrate W (step S1). In more detail, in a state in which the first pump 18 and the second pump 26 are being driven, the controller 5 allows the first supply valve 20 and the second supply valve 28 to be opened, and allows the first return valve 23 to be closed, and, as a result, a sulfuric acid aqueous solution and a phosphoric acid aqueous solution are supplied to the first supply pipe 16. As a result, the sulfuric acid aqueous solution and the phosphoric acid aqueous solution are mixed together in the first supply pipe 16, so that a mixed liquid containing phosphoric acid, sulfuric acid, and water is generated. Therefore, the mixed liquid containing phosphoric acid, sulfuric acid, and water is discharged from the first nozzle 14 toward the central portion of an upper surface of the substrate W held by the spin chuck 2.

The mixed liquid containing phosphoric acid, sulfuric acid, and water discharged from the first nozzle 14 is supplied to the central portion of the upper surface of the substrate W, and spreads outwardly along the upper surface of the substrate W while receiving a centrifugal force caused by the rotation of the substrate W. As a result, the mixed liquid containing phosphoric acid, sulfuric acid, and water is supplied to the whole area of the upper surface of the substrate W, and the upper surface of the substrate W is etched (i.e., etching process). In other words, the silicon nitride film is selectively removed from the substrate W. Etching is performed during a predetermined time, and then the controller 5 allows the first supply valve 20 and the second supply valve 28 to be closed, so that the mixed liquid stops being discharged from the first nozzle 14.

Thereafter, first rinsing is performed in which pure water that is an example of a rinsing liquid is supplied to the substrate W (step S2). In more detail, the controller 5 opens a rinsing liquid valve 13 while rotating the substrate W by the spin chuck 2, so that a rinsing liquid is discharged from the rinsing liquid nozzle 11 toward the central portion of the upper surface of the substrate W. The rinsing liquid discharged from the rinsing liquid nozzle 11 is supplied to the central portion of the upper surface of the substrate W, and spreads outwardly along the upper surface of the substrate W while receiving a centrifugal force caused by the rotation of the substrate W. As a result, the rinsing liquid is supplied to the whole area of the upper surface of the substrate W, and the mixed liquid (which contains phosphoric acid, sulfuric acid, and water) adhering to the upper surface of the substrate W is rinsed away by pure water (first rinsing). The first rinsing is performed during a predetermined time, and then the controller 5 closes the rinsing liquid valve 13, so that the pure water stops being discharged.

Thereafter, cleaning is performed in which SC1 (i.e., a mixed liquid containing aqueous ammonia and a hydrogen peroxide solution) that is an example of a chemical solution is supplied to the substrate W (step S3). In more detail, while rotating the substrate W by the spin chuck 2, the controller 5 opens the chemical solution valve 10, so that SC1 is discharged from the chemical solution nozzle 8 toward the central portion of the upper surface of the substrate W. SC1 discharged from the chemical solution nozzle 8 is supplied to the central portion of the upper surface of the substrate W, and spreads outwardly along the upper surface of the substrate W while receiving a centrifugal force caused by the rotation of the substrate W. As a result, SC1 is supplied to the whole area of the upper surface of the substrate W, and the substrate W is processed by SC1 (cleaning). Cleaning is performed during a predetermined time, and then the controller 5 closes the chemical solution valve 10, so that SC1 stops being discharged from the chemical solution nozzle 8.

Thereafter, second rinsing is performed in which pure water that is an example of a rinsing liquid is supplied to the substrate W (step S4). In more detail, while rotating the substrate W by the spin chuck 2, the controller 5 opens the rinsing liquid valve 13, so that a rinsing liquid is discharged from the rinsing liquid nozzle 11 toward the central portion of the upper surface of the substrate W. The rinsing liquid discharged from the rinsing liquid nozzle 11 is supplied to the central portion of the upper surface of the substrate W, and spreads outwardly along the upper surface of the substrate W while receiving a centrifugal force caused by the rotation of the substrate W. As a result, the rinsing liquid is supplied to the whole area of the upper surface of the substrate W, and SC1 adhering to the upper surface of the substrate W is rinsed away by pure water (second rinsing). The second rinsing is performed during a predetermined time, and then the controller 5 closes the rinsing liquid valve 13, so that the pure water stops being discharged.

Thereafter, spin drying is performed in which the substrate W is dried (step S5). In more detail, the controller 5 controls the spin motor 7 to rotate the substrate W at a high rotational speed (for example, several thousand rpm). Asa result, a great centrifugal force acts on pure water adhering to the substrate W, and this pure water is shaken off toward the surroundings of the substrate W. Thus, the pure water is removed from the substrate W, and the substrate W is dried (spin drying). The spin drying is performed during a predetermined time, and then the controller 5 allows the spin motor 7 to stop the rotation of the substrate W by controlling the spin motor 7. Thereafter, the already-processed substrate W is carried out from the spin chuck 2 by the transfer robot.

FIG. 3 is a graph showing a relationship among the concentration of phosphoric acid in a phosphoric acid aqueous solution, the temperature of the phosphoric acid aqueous solution, and the etching rate of a silicon nitride film. In FIG. 3, the etching rate is shown by the solid line when the silicon nitride film is etched by use of the phosphoric acid aqueous solution whose temperature is 150° C., 160° C., and 170° C. Additionally, in FIG. 3, the boiling point of the phosphoric acid aqueous solution is shown by the broken line.

If the concentration of phosphoric acid is fixed as shown in FIG. 3, the etching rate is the highest when the temperature of the phosphoric acid aqueous solution is 170° C., and is the second highest when the temperature of the phosphoric acid aqueous solution is 160° C. Therefore, if the concentration of phosphoric acid is fixed, the etching rate becomes higher in proportion to a rise in temperature of the phosphoric acid aqueous solution. The maximum temperature of the phosphoric acid aqueous solution is its boiling point. In other words, the phosphoric acid aqueous solution whose temperature is close to its boiling point is supplied to the silicon nitride film, and, as a result, the highest etching rate can be obtained in its concentration.

On the other hand, when the temperature of the phosphoric acid aqueous solution is 150° C., the etching rate becomes lower in proportion to a rise in concentration of phosphoric acid. Likewise, when the temperature of the phosphoric acid aqueous solution is 160° C. and 170° C., the etching rate becomes lower in proportion to a rise in concentration of phosphoric acid. Therefore, if the temperature of the phosphoric acid aqueous solution is fixed, the etching rate becomes higher in proportion to a fall in concentration of phosphoric acid. In other words, as shown in FIG. 3, the phosphoric acid aqueous solution, which has a concentration used when its liquid temperature (i.e., solution temperature) is close to its boiling point, is supplied to the silicon nitride film, and, as a result, the highest etching rate can be obtained in its liquid temperature.

As mentioned above, in either case, i.e., in a case in which the concentration of phosphoric acid is fixed or in a case in which the temperature of the phosphoric acid aqueous solution is fixed, the highest etching rate can be obtained by supplying the phosphoric acid aqueous solution whose temperature is close to its boiling point to the silicon nitride film. Additionally, when the phosphoric acid aqueous solution is supplied to the substrate W on which the silicon nitride film and the silicon oxide film are formed so as to selectively remove the silicon nitride film, the highest selection ratio can be obtained by supplying the phosphoric acid aqueous solution whose temperature is close to its boiling point to the substrate W. Therefore, the silicon nitride film can be efficiently removed by supplying a processing liquid containing a phosphoric acid aqueous solution whose temperature is close to its boiling point to the substrate W.

As described above, in the first embodiment, a mixed liquid containing phosphoric acid, sulfuric acid, and water is generated by mixing a phosphoric acid aqueous solution having room temperature and a high-temperature sulfuric acid aqueous solution having a temperature higher than the boiling point of this phosphoric acid aqueous solution together in the first supply pipe 16. The phosphoric acid aqueous solution mixed with the sulfuric acid aqueous solution is heated by the heat of the sulfuric acid aqueous solution. Furthermore, dilution heat is generated by mixing the phosphoric acid aqueous solution and the sulfuric acid aqueous solution together, and therefore the phosphoric acid aqueous solution mixed with the sulfuric acid aqueous solution is heated not only by the heat of the sulfuric acid aqueous solution but also by the dilution heat. As a result, the phosphoric acid aqueous solution contained in the mixed liquid is heated nearly to the boiling point, and the mixed liquid containing the phosphoric acid aqueous solution whose temperature is close to its boiling point is supplied to the substrate W. Therefore, when the substrate W on which the silicon nitride film is formed is processed (i.e., when etching is performed), a high selection ratio and a high etching rate can be obtained.

Additionally, the boiling point (290° C.) of sulfuric acid is higher than the boiling point (213° C.) of phosphoric acid, and therefore the temperature of the sulfuric acid aqueous solution mixed with the phosphoric acid aqueous solution can be regulated to be higher than the boiling point of this phosphoric acid aqueous solution. On the other hand, if a processing liquid to be mixed with the phosphoric acid aqueous solution is, for example, water (whose boiling point is 100° C.), the processing liquid is boiled, and therefore the temperature of the processing liquid cannot be raised higher than the boiling point of the phosphoric acid aqueous solution. Therefore, even if this processing liquid and the phosphoric acid aqueous solution are mixed together, a mixed liquid containing the phosphoric acid aqueous solution whose temperature is close to its boiling point cannot be generated. Therefore, a mixed liquid containing a phosphoric acid aqueous solution whose temperature is close to its boiling point can be reliably generated by mixing a liquid containing a processing liquid (i.e., sulfuric acid in the first embodiment) whose boiling point is higher than that of phosphoric acid and a liquid containing phosphoric acid together. Additionally, an even higher selection ratio can be obtained by supplying a mixed liquid containing sulfuric acid and a phosphoric acid aqueous solution whose temperature is close to its boiling point to the substrate W.

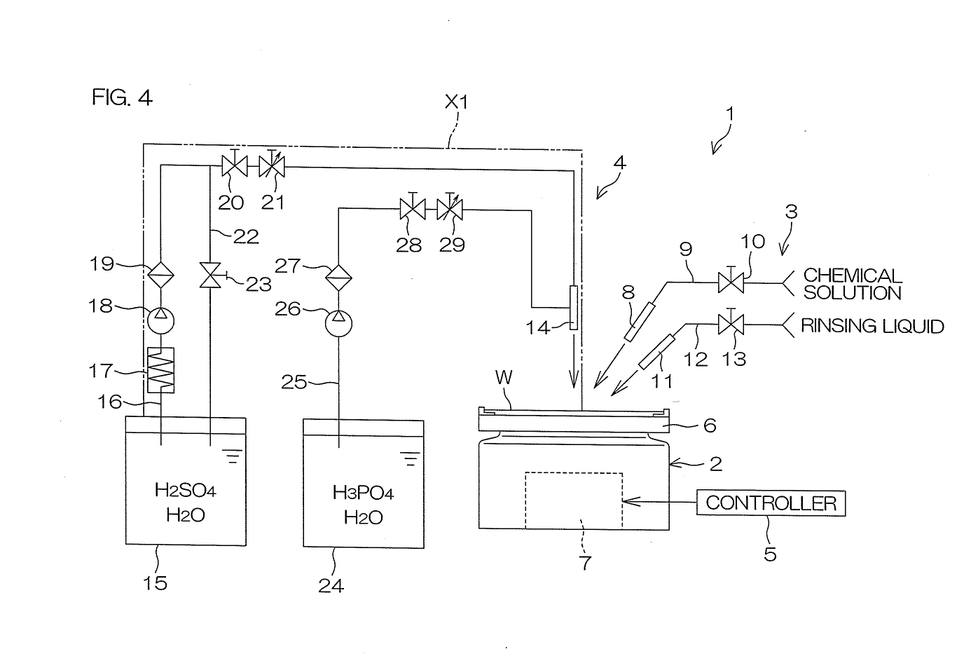

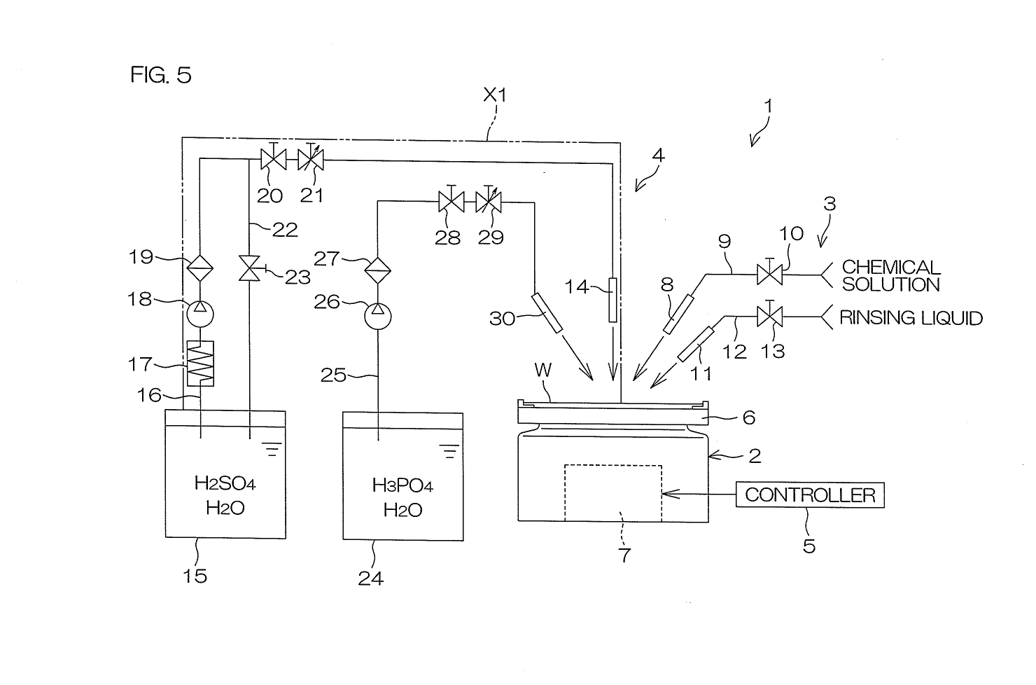

A description has been hereinbefore given of a case in which a sulfuric acid aqueous solution and a phosphoric acid aqueous solution are mixed together in the first supply pipe 16 that is a portion of the flow path X1. However, the sulfuric acid aqueous solution and the phosphoric acid aqueous solution may be mixed together in the first nozzle 14, or may be mixed together between a substrate W held by the spin chuck 2 and the first nozzle 14. In more detail, as shown in FIG. 4, the second supply pipe 25 may be connected to the first nozzle 14. Additionally, as shown in FIG. 5, the mixed liquid supply unit 4 may further include a second nozzle 30, and the second supply pipe 25 may be connected to the second nozzle 30. In this case, the sulfuric acid aqueous solution is discharged from the first nozzle 14 toward the upper surface of the substrate W, and the phosphoric acid aqueous solution is discharged from the second nozzle 30 toward the upper surface of the substrate W. Therefore, the sulfuric acid aqueous solution and the phosphoric acid aqueous solution are mixed together on the substrate W. In the structures of FIG. 1, FIG. 4, and FIG. 5, the sulfuric acid aqueous solution and the phosphoric acid aqueous solution are mixed together immediately before being supplied to the substrate W or simultaneously with being supplied to the substrate W. As a result, the mixed liquid that contains phosphoric acid, sulfuric acid, and water and whose temperature has been reliably raised is supplied to the substrate W.

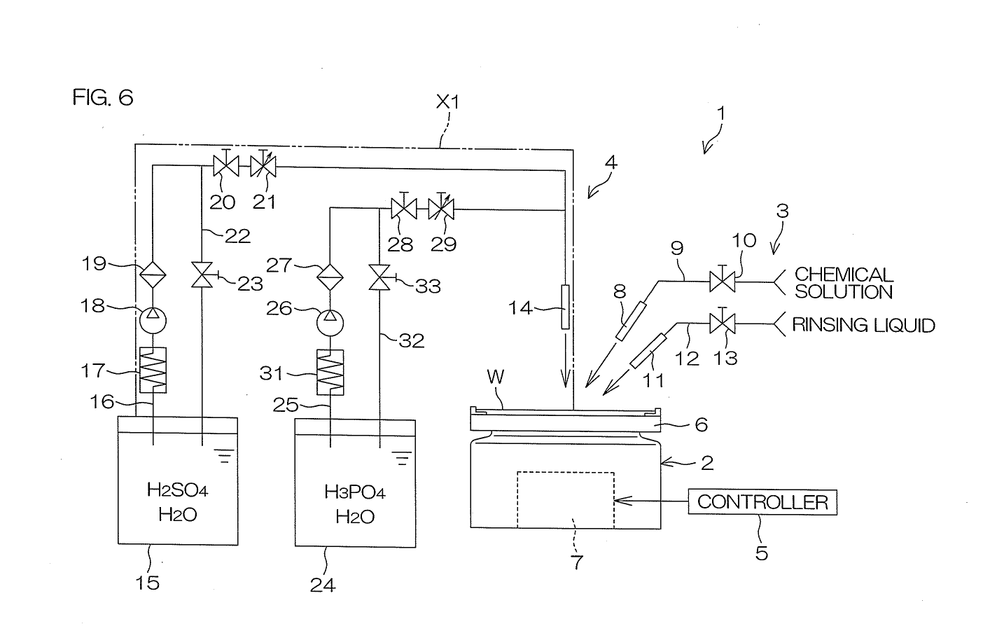

Additionally, the phosphoric acid aqueous solution stored in the second tank 24 may undergo temperature regulation although a description has been hereinbefore given of a case in which the phosphoric acid aqueous solution stored in the second tank 24 does not undergo temperature regulation. In more detail, as shown in FIG. 6, the mixed liquid supply unit 4 may further include a second heater 31 interposed in the second supply pipe 25, a second return pipe 32 by which the second tank 24 and the second supply pipe 25 are connected together, and a second return valve 33 interposed in the second return pipe 32. The second return pipe 32 is connected to the second supply pipe 25 between the second filter 27 and the second supply valve 28.

When the second supply valve 28 is closed, and the second return valve 33 is opened in a state in which the second pump 26 is being driven, the phosphoric acid aqueous solution circulates along a second circulation route including the second supply pipe 25, the second return pipe 32, and the second tank 24. As a result, the phosphoric acid aqueous solution stored in the second tank 24 is evenly heated by the second heater 31, and the liquid temperature of the phosphoric acid aqueous solution is regulated to have a temperature (for example, 30° C. to 160° C.) lower than its boiling point. Therefore, the phosphoric acid aqueous solution stored in the second tank 24 can be maintained at a temperature close to the boiling point. Additionally, the phosphoric acid aqueous solution whose temperature is close to its boiling point and the high-temperature sulfuric acid aqueous solution can be mixed together in the first supply pipe 16, and therefore a mixed liquid containing the phosphoric acid aqueous solution whose temperature is close to its boiling point can be reliably supplied to the substrate W.

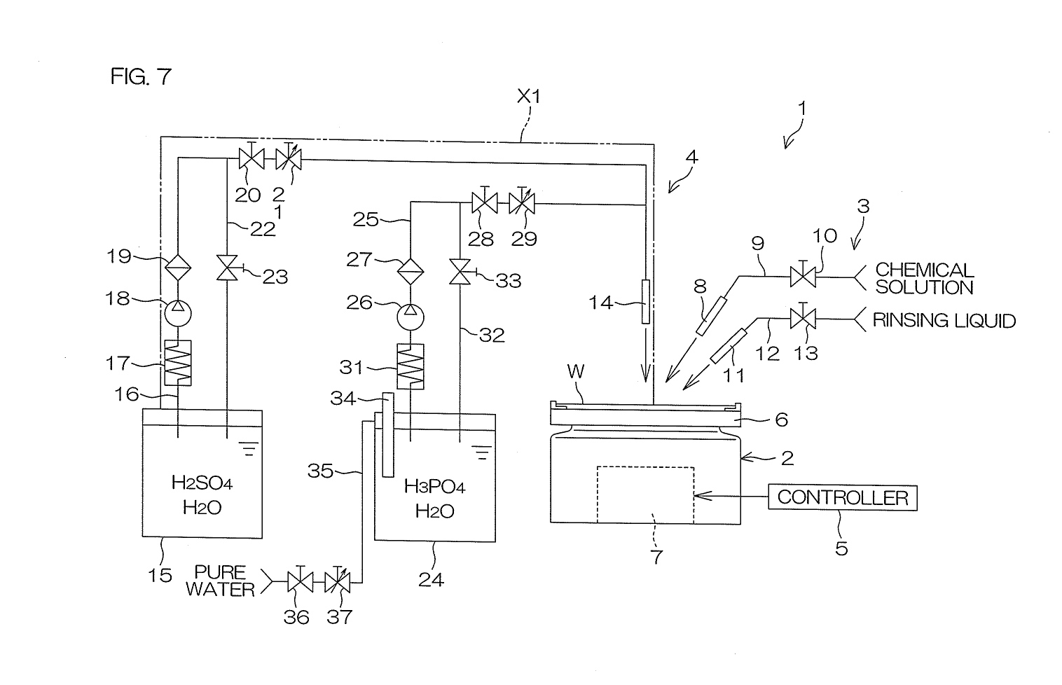

Additionally, if the phosphoric acid aqueous solution stored in the second tank 24 undergoes temperature regulation, the mixed liquid supply unit 4 may further include a first concentration detector 34 that detects the concentration of phosphoric acid in the phosphoric acid aqueous solution stored in the second tank 24, a first pure water supply pipe 35 (water supply pipe) connected to the second tank 24, and a first pure water supply valve 36 (water supply valve) and a first pure water flow regulating valve 37 both of which are interposed in the first pure water supply pipe 35 as shown in FIG. 7. The first pure water supply pipe 35 is connected to, for example, a pure water supply source disposed at a place at which the substrate processing apparatus 1 is provided. When the first pure water supply valve 36 is opened, pure water is supplied from the first pure water supply pipe 35 to the second tank 24 at a flow rate corresponding to the valve opening of the first pure water flow regulating valve 37. As a result, the phosphoric acid aqueous solution stored in the second tank 24 is diluted, and the concentration of phosphoric acid is lowered. The pure water supplied from the first pure water supply pipe 35 to the second tank 24 may be pure water having room temperature, or may be pure water (warm water) that has undergone temperature regulation within the range of, for example, 30° C. to 90° C.

If the phosphoric acid aqueous solution stored in the second tank 24 undergoes temperature regulation, there is a possibility that the concentration of phosphoric acid will be raised by the evaporation of moisture contained in the phosphoric acid aqueous solution. Therefore, the concentration of phosphoric acid in the phosphoric acid aqueous solution stored in the second tank 24 is detected by the first concentration detector 34, and, if the concentration of phosphoric acid is raised, the concentration of phosphoric acid can be stabilized by supplying pure water from the first pure water supply pipe 35 to the second tank 24. As a result, the concentration of phosphoric acid in a mixed liquid (which contains phosphoric acid, sulfuric acid, and water) to be supplied to the substrate W can be stabilized. Additionally, the phosphoric acid aqueous solution stored in the second tank 24 can be reliably maintained at a temperature close to its boiling point by controlling the temperature of the phosphoric acid aqueous solution and the concentration of phosphoric acid.

### Second Embodiment

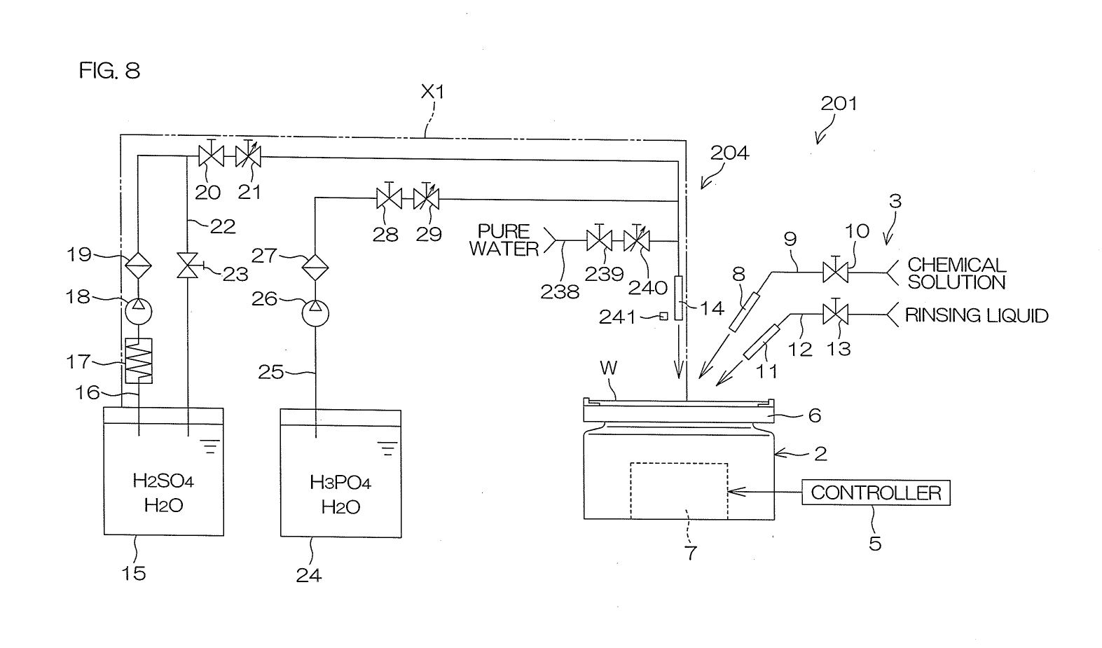

FIG. 8 is a schematic view showing a schematic structure of a substrate processing apparatus 201 according to a second embodiment of the present invention. In FIG. 8, the same reference character is given to the same component as in FIGS. 1 to 7 shown above, and a description of the same component is omitted.

A main difference between this second embodiment and the above-mentioned first embodiment is that pure water is mixed with a sulfuric acid aqueous solution and a phosphoric acid aqueous solution in the flow path X1 for a processing liquid.

In more detail, a mixed liquid supply unit 204 provided in the substrate processing apparatus 201 includes a second pure water supply pipe 238 (water supply pipe) connected to a pure water supply source, a second pure water supply valve 239 and a second pure water flow regulating valve 240 (flow regulating valve) both of which are interposed in the second pure water supply pipe 238, and a temperature detector 241 that detects the temperature of a mixed liquid containing phosphoric acid, sulfuric acid, and water in the first nozzle 14.

The second pure water supply pipe 238 is connected to the first supply pipe 16 near the first nozzle 14. The opening and closing of the second pure water supply valve 239 is controlled by the controller 5. Based on the output of the temperature detector 241, the valve opening of the second pure water flow regulating valve 240 is regulated by the controller 5. Pure water is supplied from the second pure water supply pipe 238 to the first supply pipe 16 by opening the second pure water supply valve 239 at a flow rate corresponding to the valve opening of the second pure water flow regulating valve 240. The pure water supplied from the second pure water supply pipe 238 to the first supply pipe 16 may be pure water having room temperature, or may be pure water (warm water) that has undergone temperature regulation within the range of, for example, 30° C. to 90° C.

In a state in which the first pump 18 and the second pump 26 are being driven, the controller 5 opens the first supply valve 20, the second supply valve 28, and the second pure water supply valve 239, and closes the first return valve 23. As a result, a sulfuric acid aqueous solution, a phosphoric acid aqueous solution, and pure water are supplied to the first supply pipe 16. Therefore, the pure water is mixed with the sulfuric acid aqueous solution and the phosphoric acid aqueous solution in the first supply pipe 16. If the concentration of phosphoric acid in the phosphoric acid aqueous solution stored in the second tank 24 is high, water contained in the phosphoric acid aqueous solution is small in quantity. Therefore, in this case, dilution heat generated by mixing the sulfuric acid aqueous solution and the phosphoric acid aqueous solution together is low. Therefore, great dilution heat can be obtained by supplying pure water to the first supply pipe 16 while sufficiently diluting the sulfuric acid aqueous solution in the first supply pipe 16.

Furthermore, based on the output of the temperature detector 241, the controller 5 controls the valve opening of the second pure water flow regulating valve 240. As a result, the flow rate of pure water to be supplied to the first supply pipe 16 is regulated. The controller 5 can increase dilution heat by increasing the flow rate of pure water to be supplied to the first supply pipe 16. On the other hand, the controller can decrease dilution heat by decreasing the flow rate of pure water to be supplied to the first supply pipe 16. Therefore, the controller 5 regulates the valve opening of the second pure water flow regulating valve 240, and, as a result, the temperature of a mixed liquid containing phosphoric acid, sulfuric acid, and water is regulated. Hence, a mixed liquid containing a phosphoric acid aqueous solution whose temperature is close to its boiling point can be reliably supplied to the substrate W.

A liquid containing water, such as carbonated water, hydrogen water, or aqueous hydrochloric acid of dilute concentration (e.g., about 10 to 100 ppm), may be supplied from the second pure water supply pipe 238 to the first supply pipe 16 although a description has been hereinbefore given of a case in which pure water is supplied from the second pure water supply pipe 238 to the first supply pipe 16.

Additionally, the second pure water supply pipe 238 may be connected to the second supply pipe 25, or may be connected to the first nozzle 14 although a description has been hereinbefore given of a case in which the second pure water supply pipe 238 is connected to the first supply pipe 16.

Additionally, the mixed liquid supply unit 204 may include a pure water nozzle (not shown), and the second pure water supply pipe 238 may be connected to the pure water nozzle. In this case, pure water discharged from the pure water nozzle is mixed with a sulfuric acid aqueous solution and a phosphoric acid aqueous solution on the substrate W.

Additionally, the temperature detector 241 may detect the temperature of a mixed liquid containing phosphoric acid, sulfuric acid, and water in the first supply pipe 16, or may detect the temperature of the mixed liquid between the first nozzle 14 and the substrate W held by the spin chuck 2 although a description has been hereinbefore given of a case in which the temperature detector 241 detects the temperature of a mixed liquid containing phosphoric acid, sulfuric acid, and water in the first nozzle 14.

### Third Embodiment

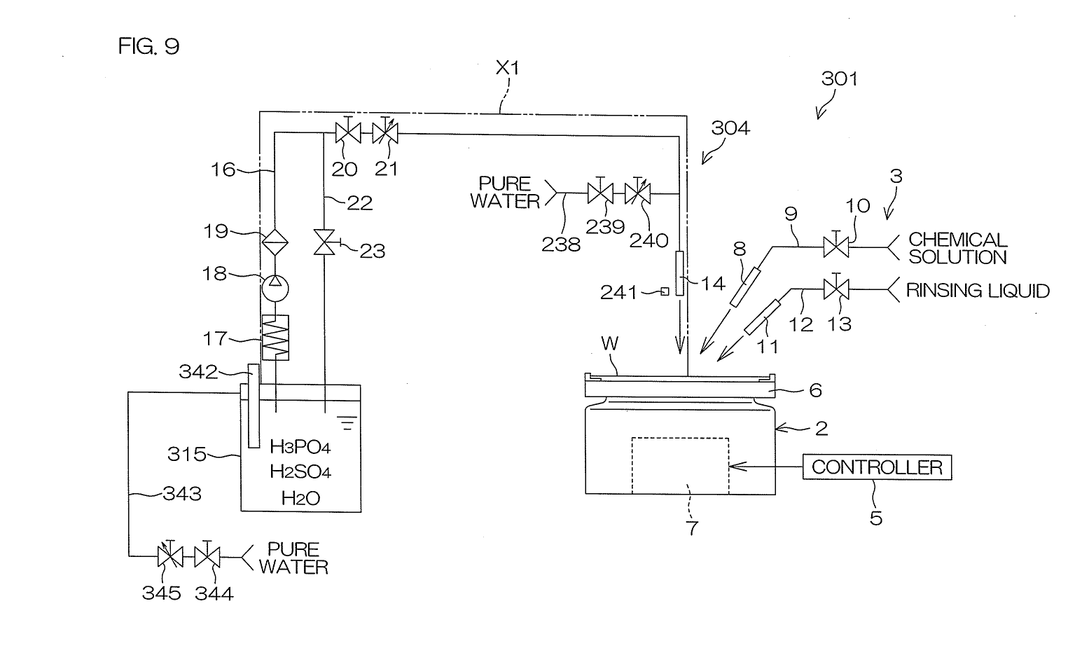

FIG. 9 is a schematic view showing a schematic structure of a substrate processing apparatus 301 according to a third embodiment of the present invention. In FIG. 9, the same reference character is given to the same component as in FIGS. 1 to 8 shown above, and a description of the same component is omitted.

A main difference between this third embodiment and the above-mentioned second embodiment is that a mixed liquid containing phosphoric acid, sulfuric acid, and water is stored in the first tank 315, and, however, the second tank 24 and a structure relevant to this tank are not provided.

In more detail, a mixed liquid supply unit 304 provided in the substrate processing apparatus 301 includes a first nozzle 14 that discharges a processing liquid toward the central portion of an upper surface of a substrate W held by a spin chuck 2, a first tank 315 (mixed liquid tank) in which a mixed liquid containing phosphoric acid, sulfuric acid, and water is stored, a first supply pipe 16 by which the first nozzle 14 and the first tank 315 are connected together, a first heater 17, a first pump 18, a first filter 19, a first supply valve 20, and a first flow regulating valve 21 that are interposed in the first supply pipe 16, a first return pipe 22 by which the first tank 315 and the first supply pipe 16 are connected together, and a first return valve 23 interposed in the first return pipe 22.

The mixed liquid (which contains phosphoric acid, sulfuric acid, and water) stored in the first tank 315 is maintained at, for example, a temperature close to the boiling point of this mixed liquid. The mixed liquid stored in the first tank 315 is mixed in the first supply pipe 16 with pure water supplied from the second pure water supply pipe 238 to the first supply pipe 16. As a result, the sulfuric acid contained in the mixed liquid is diluted, and dilution heat is generated. Therefore, this dilution heat restrains or prevents the mixed liquid from being lowered in temperature even if the mixed liquid is deprived of its heat by the first supply pipe 16 or by the first nozzle 14. Hence, the mixed liquid containing a phosphoric acid aqueous solution whose temperature is close to its boiling point is supplied to the substrate W held by the spin chuck 2. Additionally, phosphoric acid, sulfuric acid, and water are pre-mixed together in the first tank 315, and therefore an evenly-mixed liquid can be supplied to the substrate W. Hence, evenness in processing can be improved.

The mixed liquid supply unit 304 further includes a third concentration detector 342 that detects the concentration of phosphoric acid in the mixed liquid stored in the first tank 315, a third pure water supply pipe 343 (tank pipe) connected to the first tank 315, and a third pure water supply valve 344 and a third pure water flow regulating valve 345 that are interposed in the third pure water supply pipe 343. The third pure water supply pipe 343 is connected to, for example, a pure water supply source disposed at a place at which the substrate processing apparatus 301 is provided. When the controller 5 opens the third pure water supply valve 344 based on an output emitted from the third concentration detector 342, pure water is supplied from the third pure water supply pipe 343 to the first tank 315 at a flow rate corresponding to the valve opening of the third pure water flow regulating valve 345. The pure water supplied from the third pure water supply pipe 343 to the first tank 315 may be pure water having room temperature, or may be pure water (warm water) that has undergone temperature regulation within the range of, for example, 30° C. to 90° C. Pure water is supplied from the third pure water supply pipe 343 to the first tank 315, and hence the concentration of phosphoric acid in the mixed liquid containing phosphoric acid, sulfuric acid, and water is controlled. In other words, the temperature of the mixed liquid and the concentration of phosphoric acid in the mixed liquid can be controlled, and therefore the mixed liquid stored in the first tank 315 can be reliably maintained at a temperature close to its boiling point.

### Fourth Embodiment

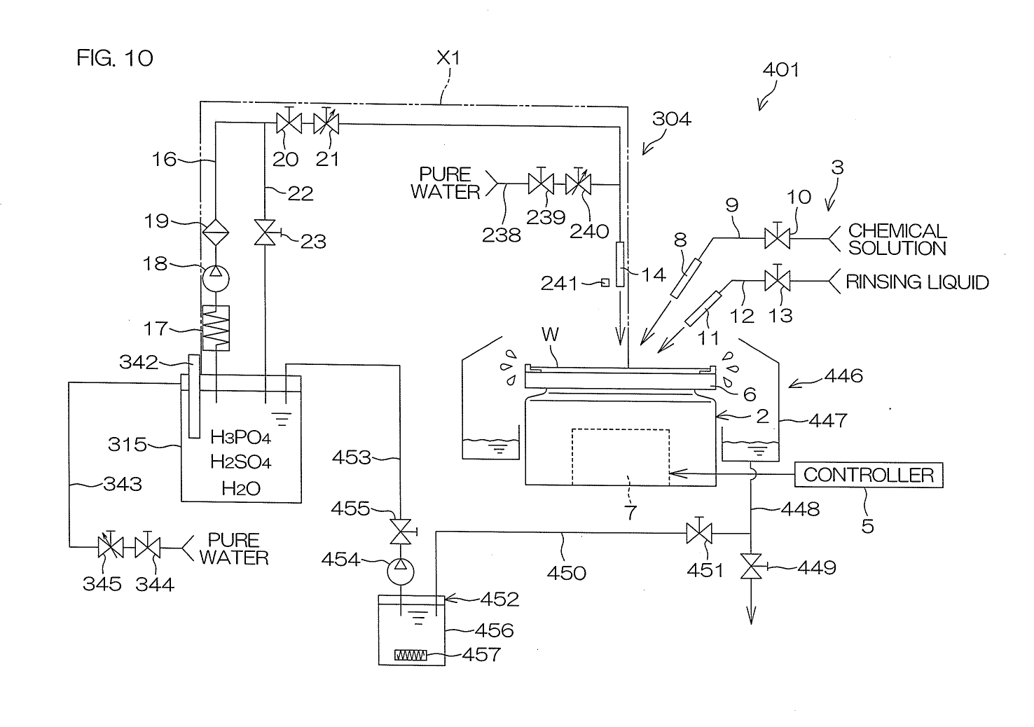

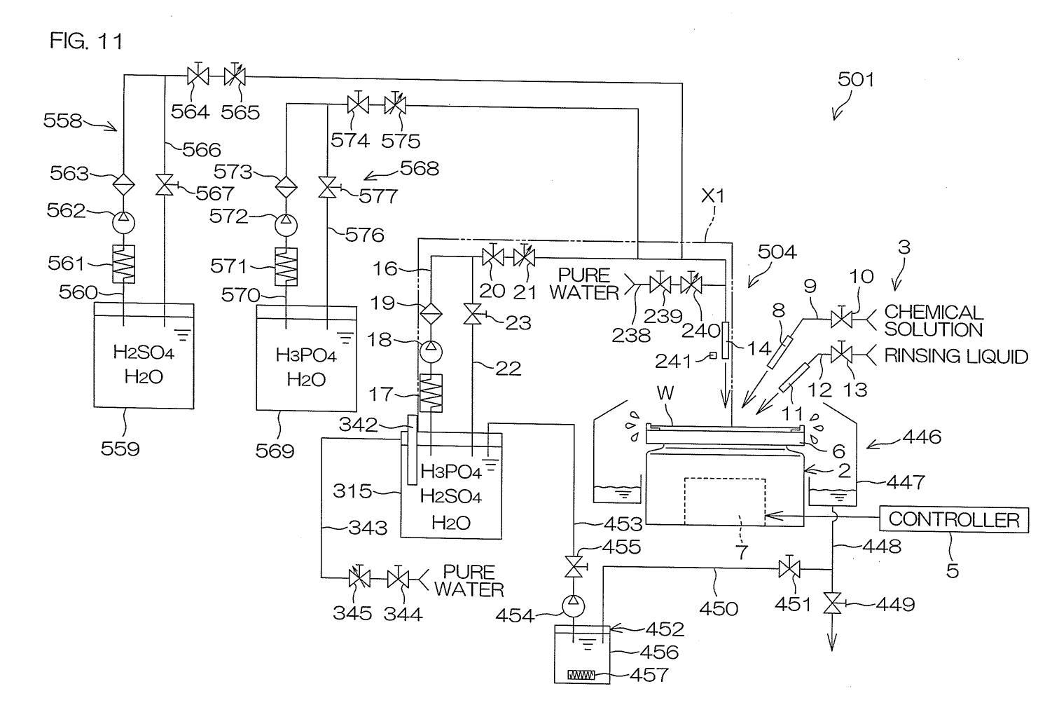

FIG. 10 is a schematic view showing a schematic structure of a substrate processing apparatus 401 according to a fourth embodiment of the present invention. In FIG. 10, the same reference character is given to the same component as in FIGS. 1 to 9 shown above, and a description of the same component is omitted.

A main difference between this fourth embodiment and the above-mentioned third embodiment is that a mixed liquid (which contains phosphoric acid, sulfuric acid, and water) supplied to the substrate W is collected and reused.

In more detail, the substrate processing apparatus 401 further includes a collecting unit 446 that collects the processing liquid supplied to the substrate W held by the spin chuck 2 and that supplies the collected processing liquid to the first tank 315. The collecting unit 446 includes a cup 447 that surrounds the spin base 6, a waste solution pipe 448 connected to the cup 447, and a waste solution valve 449 interposed in the waste solution pipe 448. The collecting unit 446 further includes a first collecting pipe 450 connected to the waste solution pipe 448, a first collecting valve 451 interposed in the first collecting pipe 450, a water evaporation unit 452 connected to the first collecting pipe 450, a second collecting pipe 453 by which the water evaporation unit 452 and the first tank 315 are connected together, and a collecting pump 454 and a second collecting valve 455 that are interposed in the second collecting pipe 453.

The processing liquid discharged around the substrate W is received by the cup 447. Thereafter, the processing liquid caught by the cup 447 is discharged to the waste solution pipe 448. The first collecting pipe 450 is connected to the waste solution pipe 448 upstream from the waste solution valve 449 (i.e., on the side of the cup 447). Therefore, the processing liquid caught by the cup 447 is supplied to the first collecting pipe 450 via the waste solution pipe 448 in a state in which the waste solution valve 449 is closed, and the first collecting valve 451 is opened. On the other hand, the processing liquid caught by the cup 447 is discharged to a waste solution device (not shown) via the waste solution pipe 448 in a state in which the waste solution valve 449 is opened, and the first collecting valve 451 is closed.

The controller 5 controls the opening and closing of the waste solution valve 449 and the opening and closing of the first collecting valve 451 so that the mixed liquid (which contains phosphoric acid, sulfuric acid, and water) supplied to the substrate W is collected into the first collecting pipe 450. The controller 5 may allow the first collecting pipe 450 to collect all the mixed liquid supplied to the substrate W, or may allow the first collecting pipe 450 to collect a portion of the mixed liquid supplied to the substrate W. In the fourth embodiment, the controller 5 controls the opening and closing of the waste solution valve 449 and the opening and closing of the first collecting valve 451, and, as a result, a portion of the mixed liquid supplied to the substrate W is collected into the first collecting pipe 450, and the remaining mixed liquid is discharged.

The water evaporation unit 452 includes a collecting tank 456 in which a mixed liquid containing phosphoric acid, sulfuric acid, and water is stored, and a collecting heater 457 that heats the mixed liquid stored in the collecting tank 456. The mixed liquid collected into the first collecting pipe 450 is supplied to the collecting tank 456. When the collecting pump 454 is driven in a state in which the second collecting valve 455 is opened, the mixed liquid stored in the collecting tank 456 is supplied from the second collecting pipe 453 to the first tank 315. The mixed liquid supplied from the second collecting pipe 453 to the first tank 315 flows along the flow path X1, and is again supplied to the substrate W held by the spin chuck 2.

The mixed liquid stored in the first tank 315 is mixed with pure water in the flow path X1, and is then supplied to the substrate W. Therefore, the concentration of water in the mixed liquid collected into the first collecting pipe 450 is higher than the concentration of water in the mixed liquid stored in the first tank 315. Water contained in the mixed liquid stored in the collecting tank 456 is evaporated by being heated by the collecting heater 457. As a result, the concentration of water in the mixed liquid is regulated. Therefore, the mixed liquid in which the concentration of water has been regulated is supplied from the collecting tank 456 to the first tank 315. Hence, the concentration of phosphoric acid in the mixed liquid stored in the first tank 315 is restrained from being changed. Therefore, the mixed liquid having a stable concentration of phosphoric acid is supplied to the substrate W held by the spin chuck 2.

As described above, in the fourth embodiment, the mixed liquid containing phosphoric acid, sulfuric acid, and water supplied to the substrate W is collected by the collecting unit 446. Thereafter, the thus collectedmixed liquid is supplied to the first tank 315. Therefore, the thus collected mixed liquid is again supplied to the substrate W, and is reused. As a result, the consumption of the mixed liquid is reduced. If a substrate W on which a silicon nitride film is formed is processed by the mixed liquid containing phosphoric acid, sulfuric acid, and water (i.e., if etching is performed by the mixed liquid), siloxane is contained in the collected mixed liquid. Therefore, in this case, the mixed liquid containing siloxane is supplied to the substrate W without beforehand allowing the mixed liquid containing phosphoric acid, sulfuric acid, and water stored in the first tank 315 to contain siloxane. Hence, the selection ratio in etching can be improved.

### Fifth Embodiment

FIG. 11 is a schematic view showing a schematic structure of a substrate processing apparatus 501 according to a fifth embodiment of the present invention. In FIG. 11, the same reference character is given to the same component as in FIGS. 1 to 10 shown above, and a description of the same component is omitted.

A main difference between this fifth embodiment and the above-mentioned fourth embodiment is that a sulfuric acid aqueous solution and a phosphoric acid aqueous solution that have not yet been used are mixed with a mixed liquid containing phosphoric acid, sulfuric acid, and water that has been collected.

In more detail, a mixed liquid supply unit 504 provided in the substrate processing apparatus 501 includes a sulfuric acid supply unit 558 (first supply unit) that supplies a sulfuric acid aqueous solution to the flow path X1. The sulfuric acid supply unit 558 includes a sulfuric acid tank 559 in which a sulfuric acid aqueous solution is stored, a sulfuric acid supply pipe 560 by which the first supply pipe 16 and the sulfuric acid tank 559 are connected together, a sulfuric acid heater 561, a sulfuric acid pump 562, a sulfuric acid filter 563, a sulfuric acid supply valve 564, and a sulfuric acid flow regulating valve 565 that are interposed in the sulfuric acid supply pipe 560, a sulfuric acid return pipe 566 by which the sulfuric acid tank 559 and the sulfuric acid supply pipe 560 are connected together, and a sulfuric acid return valve 567 interposed in the sulfuric acid return pipe 566.

The mixed liquid supply unit 504 further includes a phosphoric acid supply unit 568 (second supply unit) that supplies a phosphoric acid aqueous solution to the flow path X1. The phosphoric acid supply unit 568 includes a phosphoric acid tank 569 in which a phosphoric acid aqueous solution is stored, a phosphoric acid supply pipe 570 by which the first supply pipe 16 and the phosphoric acid tank 569 are connected together, a phosphoric acid heater 571, a phosphoric acid pump 572, a phosphoric acid filter 573, a phosphoric acid supply valve 574, and a phosphoric acid flow regulating valve 575 that are interposed in the phosphoric acid supply pipe 570, a phosphoric acid return pipe 576 by which the phosphoric acid tank 569 and the phosphoric acid supply pipe 570 are connected together, and a phosphoric acid return valve 577 interposed in the phosphoric acid return pipe 576.

One end of the sulfuric acid supply pipe 560 is connected to the sulfuric acid tank 559, and the other end of the sulfuric acid supply pipe 560 is connected to the first supply pipe 16. The sulfuric acid heater 561, the sulfuric acid pump 562, the sulfuric acid filter 563, the sulfuric acid supply valve 564, and the sulfuric acid flow regulating valve 565 are interposed in the sulfuric acid supply pipe 560 in this order from the side of the sulfuric acid tank 559. The sulfuric acid return pipe 566 is connected to the sulfuric acid supply pipe 560 between the sulfuric acid filter 563 and the sulfuric acid supply valve 564. The sulfuric acid aqueous solution stored in the sulfuric acid tank 559 is supplied to the sulfuric acid supply pipe 560 by a sucking force of the sulfuric acid pump 562. The sulfuric acid aqueous solution pumped out from the sulfuric acid tank 559 by the sulfuric acid pump 562 is heated by the sulfuric acid heater 561. Furthermore, the sulfuric acid aqueous solution pumped out by the sulfuric acid pump 562 is filtered by the sulfuric acid filter 563. As a result, foreign substances contained in the sulfuric acid aqueous solution are removed.

When the sulfuric acid supply valve 564 is opened, and the sulfuric acid return valve 567 is closed in a state in which the sulfuric acid pump 562 is being driven, the sulfuric acid aqueous solution pumped out from the sulfuric acid tank 559 is supplied to the first supply pipe 16 via the sulfuric acid supply pipe 560. On the other hand, when the sulfuric acid supply valve 564 is closed, and the sulfuric acid return valve 567 is opened in a state in which the sulfuric acid pump 562 is being driven, the sulfuric acid aqueous solution pumped out from the sulfuric acid tank 559 returns to the sulfuric acid tank 559 via the sulfuric acid supply pipe 560 and the sulfuric acid return pipe 566. Therefore, the sulfuric acid aqueous solution circulates along a circulation route including the sulfuric acid supply pipe 560, the sulfuric acid return pipe 566, and the sulfuric acid tank 559. As a result, the sulfuric acid aqueous solution stored in the sulfuric acid tank 559 is evenly heated by the sulfuric acid heater 561, and the liquid temperature of the sulfuric acid aqueous solution is regulated within the range of, for example, 60° C. to 190° C.

Likewise, one end of the phosphoric acid supply pipe 570 is connected to the phosphoric acid tank 569, and the other end of the phosphoric acid supply pipe 570 is connected to the first supply pipe 16. The phosphoric acid heater 571, the phosphoric acid pump 572, the phosphoric acid filter 573, the phosphoric acid supply valve 574, and the phosphoric acid flow regulating valve 575 are interposed in the phosphoric acid supply pipe 570 in this order from the side of the phosphoric acid tank 569. The phosphoric acid return pipe 576 is connected to the phosphoric acid supply pipe 570 between the phosphoric acid filter 573 and the phosphoric acid supply valve 574. The phosphoric acid aqueous solution stored in the phosphoric acid tank 569 is supplied to the phosphoric acid supply pipe 570 by a sucking force of the phosphoric acid pump 572. The phosphoric acid aqueous solution pumped out from the phosphoric acid tank 569 by the phosphoric acid pump 572 is heated by the phosphoric acid heater 571. Furthermore, the phosphoric acid aqueous solution pumped out by the phosphoric acid pump 572 is filtered by the phosphoric acid filter 573. As a result, foreign substances contained in the phosphoric acid aqueous solution are removed.

When the phosphoric acid supply valve 574 is opened, and the phosphoric acid return valve 577 is closed in a state in which the phosphoric acid pump 572 is being driven, the phosphoric acid aqueous solution pumped out from the phosphoric acid tank 569 is supplied to the first supply pipe 16 via the phosphoric acid supply pipe 570. On the other hand, when the phosphoric acid supply valve 574 is closed, and the phosphoric acid return valve 577 is opened in a state in which the phosphoric acid pump 572 is being driven, the phosphoric acid aqueous solution pumped out from the phosphoric acid tank 569 returns to the phosphoric acid tank 569 via the phosphoric acid supply pipe 570 and the phosphoric acid return pipe 576. Therefore, the phosphoric acid aqueous solution circulates along a circulation route including the phosphoric acid supply pipe 570, the phosphoric acid return pipe 576, and the phosphoric acid tank 569. As a result, the phosphoric acid aqueous solution stored in the phosphoric acid tank 569 is evenly heated by the phosphoric acid heater 571, and the liquid temperature of the phosphoric acid aqueous solution is regulated within the range of, for example, 30° C. to 160° C.

The mixed liquid stored in the first tank 315 is supplied to the first supply pipe 16 at a flow rate corresponding to the valve opening of the first flow regulating valve 21. The sulfuric acid aqueous solution stored in the sulfuric acid tank 559 is supplied to the first supply pipe 16 at a flow rate corresponding to the valve opening of the sulfuric acid flow regulating valve 565. The phosphoric acid aqueous solution stored in the phosphoric acid tank 569 is supplied to the first supply pipe 16 at a flow rate corresponding to the valve opening of the phosphoric acid flow regulating valve 575. Pure water flowing through the second pure water supply pipe 238 is supplied to the first supply pipe 16 at a flow rate corresponding to the valve opening of the second pure water flow regulating valve 240. As a result, the mixed liquid, the sulfuric acid aqueous solution, the phosphoric acid aqueous solution, and the pure water are mixed together in the first supply pipe 16.

A mixed liquid (i.e., a mixed liquid containing siloxane) used to process the substrate W is contained in the mixed liquid stored in the first tank 315. On the other hand, the sulfuric acid aqueous solution and the phosphoric acid aqueous solution stored in the sulfuric acid tank 559 and the phosphoric acid tank 569, respectively, and the pure water supplied from the second pure water supply pipe 238 to the first supply pipe 16 are unused-processing liquids (new liquids). Therefore, the mixed liquid supplied to the first supply pipe 16 from the first tank 315 is diluted by the sulfuric acid aqueous solution, the phosphoric acid aqueous solution, and the pure water. Therefore, siloxane is restrained from rising in concentration. Hence, a mixed liquid that contains siloxane having a high concentration (i.e., a mixed liquid containing phosphoric acid, sulfuric acid, and water containing siloxane) is restrained or prevented from being supplied to the substrate W. Therefore, a compound that contains silicon precipitated from the mixed liquid is restrained or prevented from adhering to the substrate W.

A description has been hereinbefore given of a case in which the sulfuric acid supply pipe 560 and the phosphoric acid supply pipe 570 are connected to the first supply pipe 16, and the sulfuric acid aqueous solution stored in the sulfuric acid tank 559 and the phosphoric acid aqueous solution stored in the phosphoric acid tank 569 are supplied to the first supply pipe 16. However, the sulfuric acid supply pipe 560 and the phosphoric acid supply pipe 570 may be connected to the first tank 315, and the sulfuric acid aqueous solution stored in the sulfuric acid tank 559 and the phosphoric acid aqueous solution stored in the phosphoric acid tank 569 may be supplied to the first tank 315.

### Other Embodiments

Although the embodiments of the present invention have been described above, the present invention is not limited to the contents of the above-mentioned first to fifth embodiments, and can be variously modified within the scope of the appended claims.

For example, as described in the above-mentioned first to fifth embodiments, the processing liquid discharged from the first nozzle 14 is supplied to the central portion of the upper surface of the substrate W held by the spin chuck 2. However, the first nozzle 14 may be moved while discharging the processing liquid from the first nozzle 14, and, accordingly, the position where the processing liquid is supplied from the first nozzle 14 to the substrate W may be moved between the central portion of the upper surface of the substrate W and the peripheral edge portion of the upper surface thereof.

Additionally, as described in the above-mentioned first to fifth embodiments, the processing liquid stored in the first tanks 15 and 315 is sucked by the first pump 17, and is supplied to the first supply pipe 16. However, gas may be supplied in the first tanks 15 and 315 so that the pressure inside the first tanks 15 and 315 is raised, and, as a result, the processing liquid stored in the first tanks 15 and 315 may be supplied to the first supply pipe 16. The same applies to a case in which the processing liquid stored in the other tanks is supplied to the pipes.

Additionally, as described in the first processing example mentioned above, the first rinsing is first performed, and then the cleaning and the second rinsing are performed.

However, spin drying may be performed without performing the cleaning and the second rinsing after performing the first rinsing.

In addition to these modifications, various design changes can be made within the scope of the appended claims.

Although the embodiments of the present invention have been described in detail, these embodiments are merely concrete examples used to clarify the technical contents of the present invention, and the present invention should not be understood by being limited to these concrete examples, and the spirit and scope of the present invention are limited solely by the appended claims.

The present application corresponds to Japanese Patent Application No. 2010-219370 filed in the Japan Patent Office on Sep. 29, 2010, and the entire disclosure of the application is incorporated herein by reference.

What is claimed is:

1. A substrate processing apparatus that processes a substrate by a mixed liquid containing phosphoric acid, sulfuric acid, and water, the substrate processing apparatus comprising:
a substrate holding unit that holds a substrate; and
a mixed liquid supply unit including a first tank in which a processing liquid to be supplied to the substrate held by the substrate holding unit is stored and a flow path for the processing liquid leading from the first tank to the substrate held by the substrate holding unit, the mixed liquid supply unit raising a temperature of a mixed liquid containing phosphoric acid, sulfuric acid, and water by supplying the phosphoric acid, the sulfuric acid, and the water to the flow path and by mixing a liquid containing the sulfuric acid and a liquid containing the water in the flow path, the mixed liquid supply unit supplying a mixed liquid containing a phosphoric acid aqueous solution whose temperature is close to its boiling point to the substrate.

2. The substrate processing apparatus according to claim 1, wherein the mixed liquid supply unit further includes a first nozzle that discharges a processing liquid toward the substrate held by the substrate holding unit, and a first supply pipe through which a processing liquid to be supplied to the first nozzle from the first tank flows, and
the flow path includes an inside of the first supply pipe, an inside of the first nozzle; and a space between the first nozzle and the substrate held by the substrate holding unit.

3. The substrate processing apparatus according to claim 1, wherein the first tank stores a mixed liquid that contains at least two among phosphoric acid, sulfuric acid, and water.

4. The substrate processing apparatus according to claim 1, wherein the mixed liquid supply unit includes:
a water supply pipe through which a liquid that contains water to be supplied to the flow path flows;
a flow regulating valve that regulates a flow rate of the liquid flowing through the water supply pipe;
a temperature detector that detects a temperature of a mixed liquid containing phosphoric acid, sulfuric acid, and water in the flow path; and
a flow controller that controls the flow regulating valve based on an output emitted from the temperature detector.

5. The substrate processing apparatus according to claim 1, wherein the first tank includes a mixed liquid tank in which a mixed liquid containing phosphoric acid, sulfuric acid, and water is stored, and
the substrate processing apparatus further comprising:
a collecting unit that collects the mixed liquid containing phosphoric acid, sulfuric acid, and water supplied to the substrate held by the substrate holding unit and that supplies the mixed liquid collected thereby to the mixed liquid tank.

6. The substrate processing apparatus according to claim 5, wherein the mixed liquid supply unit further includes:
a phosphoric acid supply unit that supplies a liquid containing phosphoric acid to at least one of the mixed liquid tank and the flow path; and
a sulfuric acid supply unit that supplies a liquid containing sulfuric acid to at least one of the mixed liquid tank and the flow path.

7. A substrate processing method of processing a substrate by a mixed liquid containing phosphoric acid, sulfuric acid, and water, the substrate processing method comprising:
a temperature raising step of raising a temperature of a mixed liquid containing phosphoric acid, sulfuric acid, and water by supplying the phosphoric acid, the sulfuric acid, and the water to a flow path for a processing liquid leading from a first tank, in which the processing liquid to be supplied to a substrate is stored, to the substrate and by mixing a liquid containing the sulfuric acid and a liquid containing the water in the flow path; and
a mixed liquid supply step of supplying a mixed liquid that has been generated in the temperature raising step and that contains a phosphoric acid aqueous solution whose temperature is close to its boiling point to the substrate.

8. A substrate processing apparatus comprising:
a substrate holding unit that holds a substrate; and
a mixed liquid supply unit that mixes a first liquid and a second liquid that are heated by being mixed together in a flow path for a processing liquid leading to a substrate held by the substrate holding unit and that supplies a mixed liquid containing the first liquid and the second liquid to the substrate.

9. The substrate processing apparatus according to claim 8, wherein
the mixed liquid supply unit includes a first liquid supply unit that supplies the first liquid to be mixed with the second liquid in the flow path, and a second liquid supply unit that supplies the second liquid to be mixed with the first liquid in the flow path, and
the first liquid supply unit includes a first tank in which the first liquid is stored, a first supply pipe connected to the first tank, and a first nozzle that is connected to the first supply pipe and that discharges the first liquid toward the substrate held by the substrate holding unit, and
the first tank, the first supply pipe, the first nozzle, and a space between the first nozzle and the substrate define the flow path.

10. The substrate processing apparatus according to claim 9, wherein the second liquid supply unit includes:
a second tank in which the second liquid is stored; and
a second supply pipe that is connected to the second tank and that is connected to at least one of the first supply pipe and the first nozzle.

11. The substrate processing apparatus according to claim 9, wherein the second liquid supply unit includes:
a second tank in which the second liquid is stored;
a second supply pipe connected to the second tank; and
a second nozzle that is connected to the second supply pipe and that discharges the second liquid toward the substrate held by the substrate holding unit.

12. The substrate processing apparatus according to claim 9, wherein the second liquid supply unit includes at least one among a tank pipe that is connected to the first tank and that supplies the second liquid to the first tank, an intermediate pipe that is connected to at least one of the first supply pipe and the first nozzle and that supplies the second liquid to at least one of the first supply pipe and the first nozzle, and a second nozzle that discharges the second liquid toward the substrate held by the substrate holding unit.

13. The substrate processing apparatus according to claim 8, wherein the mixed liquid supply unit includes:
a first tank in which the first liquid is stored;
a first circulation route along which the first liquid stored in the first tank circulates; and
a first heater that heats the first liquid circulating along the first circulation route.

14. The substrate processing apparatus according to claim 13, wherein the mixed liquid supply unit further includes:
a second tank in which the second liquid is stored;
a second circulation route along which the second liquid stored in the second tank circulates; and
a second heater that heats the second liquid circulating along the second circulation route.

15. The substrate processing apparatus according to claim 8, wherein the mixed liquid supply unit further includes:
a second tank in which the second liquid is stored;
a second circulation route along which the second liquid stored in the second tank circulates;
a second heater that heats the second liquid circulating along the second circulation route;
a concentration detector that detects a concentration of the second liquid stored in the second tank;
a water supply pipe that supplies water to the second tank;
a water supply valve interposed in the water supply pipe; and
a concentration controller that opens and closes the water supply valve based on an output emitted from the concentration detector.

16. The substrate processing apparatus according to claim 8, wherein the mixed liquid supply unit includes:
a first supply pipe through which the first liquid to be mixed with the second liquid in the flow path flows; and
a first flow regulating valve interposed in the first supply pipe.

17. The substrate processing apparatus according to claim 16, wherein the mixed liquid supply unit further includes:
a second supply pipe through which the second liquid to be mixed with the first liquid in the flow path flows; and
a second flow regulating valve interposed in the second supply pipe.

18. The substrate processing apparatus according to claim 8, wherein the mixed liquid supply unit includes:
a second supply pipe through which the second liquid to be mixed with the first liquid in the flow path flows;
a second flow regulating valve interposed in the second supply pipe;
a temperature detector that detects a temperature of the mixed liquid containing the first liquid and the second liquid in the flow path; and
a flow controller that controls the second flow regulating valve based on an output emitted from the temperature detector.

19. The substrate processing apparatus according to claim 8, wherein the mixed liquid supply unit includes a mixed liquid tank in which the mixed liquid containing the first liquid and the second liquid is stored,
the substrate processing apparatus further comprising:
a collecting unit that collects the mixed liquid supplied to the substrate held by the substrate holding unit and that supplies the mixed liquid collected thereby to the mixed liquid tank.

20. The substrate processing apparatus according to claim 19, wherein the mixed liquid supply unit includes:
a first supply unit that supplies the first liquid to at least one of the mixed liquid tank and the flow path; and
a second supply unit that supplies the second liquid to at least one of the mixed liquid tank and the flow path.

21. The substrate processing apparatus according to claim 8, wherein the substrate holding unit is a unit that horizontally holds a substrate.

22. The substrate processing apparatus according to claim 21, wherein the substrate holding unit is a unit that rotates the substrate around a vertical axis passing through a center of the substrate while horizontally holding the substrate.

23. The substrate processing apparatus according to claim 8, wherein the mixed liquid supply unit is a unit that supplies phosphoric acid, sulfuric acid, and water to the flow path, that mixes the first liquid containing at least the sulfuric acid and the second liquid containing at least the water together in the flow path, and that supplies the mixed liquid containing the phosphoric acid, the sulfuric acid, and the water to the substrate held by the substrate holding unit.

24. A substrate processing method comprising:
a mixed liquid supply step of mixing a first liquid and a second liquid that are heated by being mixed together in a flow path for a processing liquid leading to a substrate held by a substrate holding unit, and thereby supplying a mixed liquid containing the first liquid and the second liquid to the substrate.

25. The substrate processing method according to claim 24, wherein the mixed liquid supply step includes a step of mixing the first liquid and the second liquid together in at least one among a first tank in which the first liquid is stored, a first supply pipe connected to the first tank, a first nozzle that is connected to the first supply pipe and that discharges the first liquid toward the substrate held by the substrate holding unit, and a space between the first nozzle and the substrate.

26. The substrate processing method according to claim 24, wherein the mixed liquid supply step includes a first heating step of raising a temperature of the first liquid stored in a first tank by a first heater.

27. The substrate processing method according to claim 26, wherein the mixed liquid supply step further includes a second heating step of raising a temperature of the second liquid stored in a second tank by a second heater.

28. The substrate processing method according to claim 24, wherein the mixed liquid supply step includes:
a second heating step of raising a temperature of the second liquid stored in a second tank by a second heater; and
a concentration regulating step of regulating a concentration of the second liquid stored in the second tank by supplying water to the second tank.

29. The substrate processing method according to claim 24, wherein the mixed liquid supply step includes a mixing ratio changing step of changing a mixing ratio between the first liquid and the second liquid that are mixed together in the flow path.

30. The substrate processing method according to claim 24, wherein the mixed liquid supply step includes a flow rate changing step of changing a flow rate of the second liquid supplied to the flow path in accordance with a temperature of a mixed liquid containing the first liquid and the second liquid in the flow path.

31. The substrate processing method according to claim 24, further comprising:
a collecting step of collecting the mixed liquid supplied to the substrate in the mixed liquid supply step and thereafter supplying the mixed liquid collected in the collecting step to a mixed liquid tank in which the mixed liquid containing the first liquid and the second liquid is stored.

32. The substrate processing method according to claim 31, further comprising:
a mixed liquid concentration regulating step of supplying at least one of the first liquid and the second liquid to the mixed liquid collected in the collecting step and thereby regulating a concentration of the mixed liquid.

33. The substrate processing method according to claim 24, wherein the mixed liquid supply step is a step of supplying the mixed liquid containing the first liquid and the second liquid to the substrate horizontally held by the substrate holding unit.

34. The substrate processing method according to claim 33, wherein the mixed liquid supply step is a step of supplying the mixed liquid containing the first liquid and the second liquid to the substrate that is horizontally held by the substrate holding unit and that is rotating around a vertical axis passing through a center of the substrate.

35. The substrate processing method according to claim 24, wherein the mixed liquid supply step is a step of supplying phosphoric acid, sulfuric acid, and water to the flow path, mixing the first liquid containing at least the sulfuric acid and the second liquid containing at least the water together in the flow path, and supplying a mixed liquid containing the phosphoric acid, the sulfuric acid, and the water to the substrate held by the substrate holding unit.

36. The substrate processing method according to claim 35, wherein the substrate processing method is a method of processing a substrate on which a nitride film is formed, and the mixed liquid supply step is a step of etching the nitride film.
